(19) United States
(12) Patent Application Publication
(10) Pub. No.: US 2009/0284472 A1
(43) Pub. Date: Nov. 19, 2009

(54) SYSTEM AND METHOD FOR CONTROLLING AN ELECTRONIC DEVICE

(75) Inventors: Nihal J. Mehta, Plano, TX (US); Mira A. Mehta, Plano, TX (US)

Correspondence Address: MUNSCH, HARDT, KOPF & HARR, P.C.;INTELLECTUAL PROPERTY DOCKET CLERK, 3800 LINCOLN PLAZA, 500N AKARD STREET, DALLAS, TX, 75201, US

(73) Assignee: OMEGA3 SYSTEMS, INC., Plano, TX (US)

(21) Appl. No.: 12/183,218

(22) Filed: Jul. 31, 2008

Related U.S. Application Data
(60) Provisional application No. 61/054,409, filed on May 19, 2008.

(51) Int. Cl. G06F 3/02; H03K 17/94

(52) U.S. Cl. 345/169; 341/22

(57) ABSTRACT

According to one embodiment of the present invention, a method is disclosed for controlling an electronic device via a remote control device that is configured to receive alphanumeric text input, and to transmit a signal to the electronic device to switch the electronic device to a channel corresponding to the alphanumeric text input.

### BACKGROUND OF THE INVENTION

A remote control is an electronic device used for the remote operation of a machine. Commonly, remote controls are used to issue commands from a distance to televisions or other consumer electronics such as cable and satellite set-top boxes, stereo systems, and DVD players. Remote controls for these devices are usually small wireless handheld objects with an array of buttons for adjusting various settings such as a television channel, a track number, and volume. Most of these remotes communicate to the consumer electronic devices via infrared (IR) signals and a few via radio signals. They are usually powered by small size batteries.

### SUMMARY OF THE INVENTION

The present invention overcomes the disadvantages and limitations of the prior art by providing, inter alia, a remote control device operable to receive text input and correlate the text input to a particular channel.

### BRIEF DESCRIPTION OF THE DRAWINGS

FIG. 1 is a pictorial view of an embodiment of a remote control device;

FIG. 2 is a block diagram of the components of an embodiment of the remote control device of FIG. 1;

FIG. 3 is a pictorial view of the remote control device of FIG. 1 communicating with a network for sending and/or receiving data used in configuring the remote control device;

FIG. 4 is an embodiment of a data processing system in which illustrative embodiments may be implemented;

FIG. 5 depicts an embodiment of a web page for retrieving data that correlates channel names to channel numbers for at least one media provider;

FIG. 6 depicts an embodiment of a remote configuration application for generating and performing the functions associated with the disclosed embodiments;

FIG. 7 is a flowchart for retrieving data that correlates channel names to channel numbers for at least one media provider in accordance with illustrative embodiments;

FIG. 8 is a flowchart depicting a method for selecting a channel in accordance with an illustrative embodiment;

FIG. 9 is a flowchart depicting a method for selecting a channel in accordance with another illustrative embodiment; and

FIG. 10 is a flowchart depicting a method for selecting a channel in accordance with another illustrative embodiment.

### DETAILED DESCRIPTION

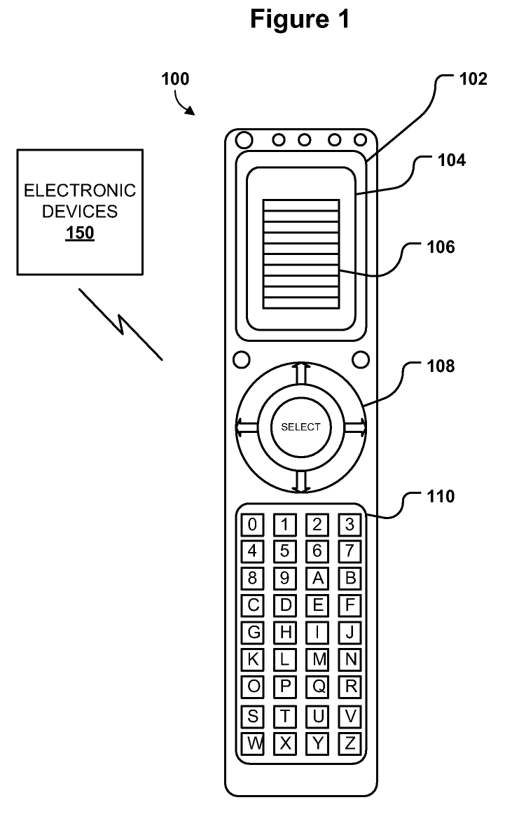

FIG. 1 is a pictorial view of an embodiment a remote control device 100. In some embodiments, remote control device 100 is preferably designed as a universal remote control device for controlling a plurality of different types of electronic devices 150 such as, but not limited to, televisions, stereos, and DVD players. However, remote control device 100 may be designed specifically for controlling just one type of electronic device.

In some embodiments, remote control device 100 comprises a screen 102. In some embodiments, screen 102 may be a touch screen capable of receiving user input. In addition, screen 102 may be used for, but is not limited to, displaying user entered input such as, but not limited to, the names of channels and or TV shows that a user desires to watch. Screen 102 may also be used to display electronic programming guides (EPGs) and/or a list of favorite channels in accordance with some embodiments. Further, in some embodiments, screen 102 may display a user interface 104. User interface 104 may be used to configure and/or execute functions associated with remote control device 100. As will be further explained, screen 102 may display a selection menu 106 in response to receiving text input and/or other types of commands from a user. For example, in some embodiments, user interface 104 may enable a user to enter alphanumeric text input to perform a keyword search of the stored electronic programming guides and display the results in selection menu 106. As referenced herein, alphanumeric text means alphabetic characters and/or a combination of alphabetic characters and numbers. In some embodiments, remote control device 100 may also be configured to accept symbols, punctuation marks, and/or other characters.

Remote control device 100 also comprises buttons 108 and keyboard 110. Buttons 108 comprises buttons for controlling electronic devices and/or for controlling the functions of remote control device 100. Keyboard 110 is used for entering alphanumeric text input. Keyboard 110 may comprise any type of layout such as, but not limited to, alphabetic order, a QWERTY style keyboard, and/or the combination of letters on each numerical button such as commonly found on telephones. In addition, keyboard 110 may comprise other keys for inserting symbols, such as, but not limited to, an “&” symbol. In some embodiments, keyboard 110 may be implemented as a touch screen keyboard.

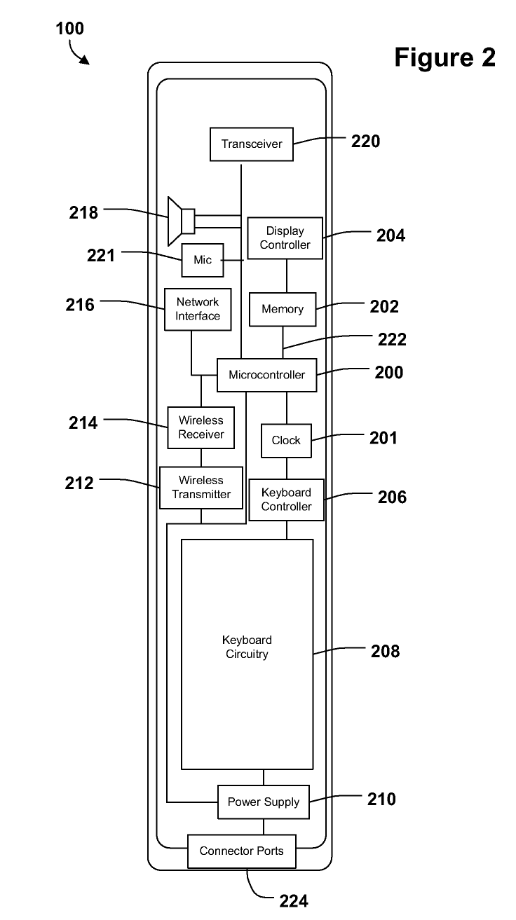

FIG. 2 depicts a high level block diagram of the internal components of an embodiment of remote control device 100. Remote control device 100 includes electrical circuitry such as a microcontroller 200. In some embodiments, in addition to the usual arithmetic and logic elements of a general purpose microprocessor, microcontroller 200 integrates additional elements such as read-write memory for data storage, read-only memory for program storage, electrically erasable programmable read-only memory (EEPROM) for permanent data storage, peripheral devices, and input/output interfaces for communicating with other components of remote control device 100 over a data bus 222. Microcontroller 200 is configured to process data and/or executes instructions for implementing the functions of remote control device 100.

In some embodiments, microcontroller 200 may be configured with, among other things, an auto-correcting mechanism for automatically correcting user entry error. For instance, in some embodiments, based on the key layout on remote control device 100, an adjacency map for each key can be created. As an example, suppose the letters “B” and “H” are the only two letters adjacent to “A” on remote control device 100. When remote control device 100 receives a non-matching alphanumeric text input such as “HBC”, remote control device 100 searches for channel names matching the combinations of the adjacent letters of the entered text. In this case, remote control device 100 may provide a list of matching combinations and/or remote control device 100 may automatically switch to the most likely matching channel name such as “ABC.” In addition, remote control device 100 may comprise other types of auto-correcting mechanisms for automatically correcting user entry error such as, but not limited to, auto-correcting misspellings and/or phonetic spellings.

In some embodiments, remote control device 100 may comprise additional memory, such as memory 202 coupled to microcontroller 200. Memory 202 may be in the form of, but not limited to, flash memory or EEPROM. Flash memory is non-volatile computer memory that can be electrically erased and reprogrammed. Non-volatile means that no power is needed to maintain the information stored in the chip. In some embodiments, memory 202 may store one or more electronic programming guides and/or data that correlates channel names to channel numbers for a specified media provider. In addition, in some embodiments, the data may also correlate channel names to show names and/or show topics.

In addition, remote control device 100 comprises keyboard circuitry 208 for supporting alphanumeric text input. In some embodiments, a keyboard controller 206 provides an interface between keyboard circuitry 208 and microcontroller 200 for handling input received from the keyboard circuitry 208.

Further, in some embodiments, remote control device 100 may comprise a network interface 216. Network interface 216 may be used to connect remote control device 100 to a network, such as the Internet, to send and receive data. In some embodiments, remote control device 100 may comprise wireless transmitter 212 and wireless receiver 214 for wirelessly sending and receiving data over a network. Additionally, in some embodiments, remote control device 100 may comprise connector ports 224 for connecting remote control device 100 to a computing device such as, but not limited to, a personal computer or laptop for downloading data from a network. Connector ports 224 may be, but are not limited to, Universal Serial Bus (USB) ports.

Remote control device 100 also comprises of a transceiver 220 for transmitting a signal to enable operation of electronic devices 150. Transceiver 220 may use any type of communication signal for communicating between remote control device 100 and electronic devices 150 such as, but not limited to, infrared (IR), Bluetooth, and radio frequency (RF). In some embodiments, remote control device 100 may also use transceiver 220 to learn from other remote devices.

In addition, in some embodiments, remote control device 100 comprises of a display controller 204. Display controller 204 is coupled to microcontroller 200 and may also be coupled to other components such as, but not limited to, memory 202. Display controller 204 is responsible for generating and rendering images and text on screen 102.

In some embodiments, remote control device 100 may also comprise speaker circuitry 218 for the generation of sound and/or audio output. For example, in some embodiments, remote control device 100 may announce the name of the selected channel and/or may verbally announce to a user that a matching channel name was not found.

Further, in some embodiments, remote control device 100 may also comprise a microphone 221 for receiving audio output. For example, in some embodiments, remote control device 100 may be configured to receive voice commands such as, but not limited to, receiving a channel name. For instance, a user may simply say “ESPN” and remote control device 100 will transmit a signal to change the television to the corresponding channel.

Additionally, in some embodiments, remote control device 100 may comprise a clock 201. For example, remote control device 100 may use clock 201 for determining the show times of shows corresponding to the entered alphanumeric text input.

The components of remote control device 100 receive power from a power supply 210. In some embodiments, power supply 210 is one or more small size battery such as, but not limited to, AA, AAA, 9V, or lithium ion battery.

The depicted components of remote control device 100 are intended merely as an illustrative example and not as an architectural limitation for the different illustrative embodiments. It should be understood by one of ordinary skill in the art that components may be added, deleted, modified, and/or combined and that such modifications are within the scope of the disclosed embodiments. For example, although, wireless transmitter 212 and wireless receiver 214 are depicted as two separate components, it should be understood that the functions of wireless transmitter 212 and wireless receiver 214 may be performed by a single component.

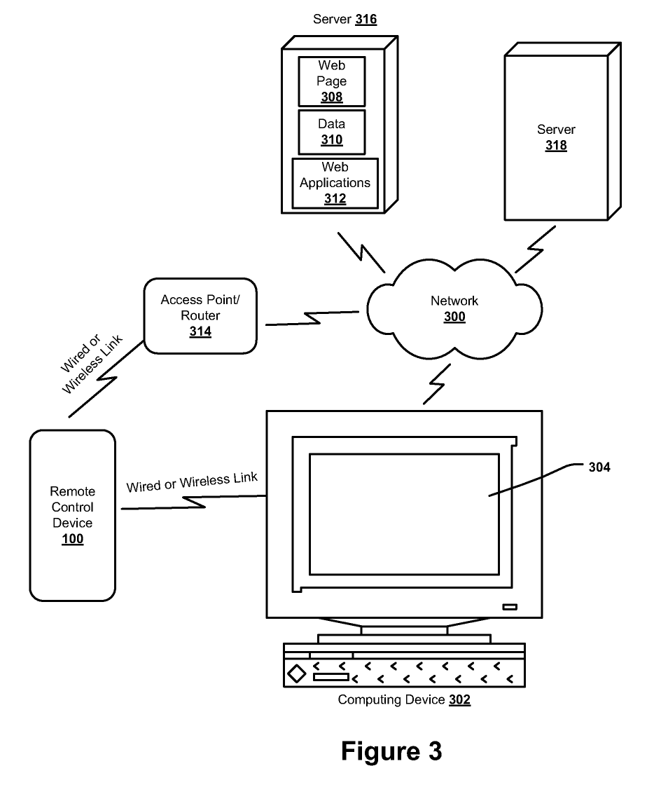

FIG. 3 is a pictorial view of remote control device 100 communicating with a network 300 such as, but not limited to, the Internet for sending and/or receiving data used in configuring remote control device 100. In some embodiments, remote control device 100 may be physically coupled to a computing device 302 through connector ports 224. Computing device 302 may be any type of computing device capable of accessing network 300 such as, but not limited to, personal computers, laptops, telephones, and/or a personal digital assistants (PDAs).

Computing device 302 may use an internet browser 304 to access data and/or web services from network 300. Internet browser 304 may be any type of internet browser such as, but not limited to, Mozilla® Firefox®. For example, computing device 302 may access a web page 308, data 310, and/or web applications 312 stored on a server such as server 316. Server 316 may comprise of one or more data processing systems, i.e., a server farm.

Data 310 may comprise data correlating channel names to channel numbers for configuring remote control device 100 to switch to a particular channel number in response to receiving text input of a channel name. In some embodiments, in addition to correlating channel names to channel numbers, data 310 may also comprise data correlating channel logos, show names, show times, show keywords, and/or show categories, i.e., sports, musicals, home improvement, etc. . . . , to a channel name and/or number. For example, in some embodiments, remote control device 100 may be configured to retrieve a channel broadcasting Wimbledon in response to receiving a text input of “tennis.” Therefore, a user of remote control device 100 is able to quickly locate and switch to a desired broadcast without knowing either the channel name or number.

Further, in some embodiments, data 310 may comprise data for configuring remote control device 100 to operate a particular electronic device, such as, but not limited to, a particular brand of television. For example, a user may access web page 308 using computing device 302 and enter in identifying information of a particular electronic device such as, but not limited to, the type, brand, and/or model number of the device. Server 316 retrieves and transmits the appropriate data necessary to configure remote control device 100 to control the particular electronic device. The data is then transferred from computing device 302 to remote control device 100.

However, in some embodiments, the remote control device 100 may be configured to send and retrieve data to and from server 316 without use of computing device 302 and/or web page 308. For example, remote control device 100 may communicate to server 316 over network 300 through a wired or wireless access point/router 314. In addition, in some embodiments, remote control device 100 may be programmed to automatically send and retrieve data such as, but not limited to, channel lineup updates, device codes, and/or software/firmware updates without user intervention. For example, in some embodiments, remote control device 100 may automatically receive data for modifying remote control device 100's capabilities such as, but not limited to, adding additional features/functions to remote control device 100.

In addition, in some embodiments, the user may specify the electronic devices to control, applicable channel lineups, frequency of updates, etc. on remote control device 100 (using a touch screen such as screen 102, keyboard 110, and/or buttons 108). Remote control device 100 may be configured to transmit the data to server 316 over network 300 through a wired or wireless access point/router 314 to send and retrieve the appropriate configuration information. Alternatively, in some embodiments, a user may configure this information using web page 308, and remote control device 100 would automatically communicate with server 316 to send and retrieve the appropriate configuration information over a wired or wireless network.

In addition, in some embodiments, server 316 may store and/or execute web applications 312 to retrieve data from other servers, such as server 318 for configuring remote control device 100. For example, web applications 312 executing on server 316 may request the electronic programming guide for a specified media provider from another web application executing on server 318. In some embodiments, web applications 312 may enable a user to retrieve data associated with one or more media providers. For example, remote control device 100 may be configured to control one or more electronic devices associated with different electronic programming guides.

Further, in some embodiments, server 316 may store and/or execute web applications 312 to enable a user to generate and download a list or grouping of favorite shows and/or channels to remote control device 100. In some embodiments, remote control device 100 may be configured to cycle through the channels within the favorites list in response to a receiving a user command. The order of cycling through the channels may be alphabetical, numerical, user specified, based on a ranking of past selections, and/or random. In some embodiments, multiple favorites list may be generated and downloaded by one or more users accessing web page 308 through computing device 302 and/or remote control device 100 may be programmed to automatically retrieve the data from server 316 through a wired or wireless access point 304. In these embodiments, remote control device 100 may be configured to enable a user to switch between the plurality of favorites lists.

In addition, in some embodiments, remote control device 100 may be configured to store usage information such as, but not limited to, selected channels and/or shows. The stored usage data may be transmitted to web applications 312. Web applications 312 may process the usage data and generate a profile for the user. For example, if the usage information indicates that the user routinely watches comedies, then web applications 312 may automatically select similar programs and associate them on a “Favorites” list as will be further described below.

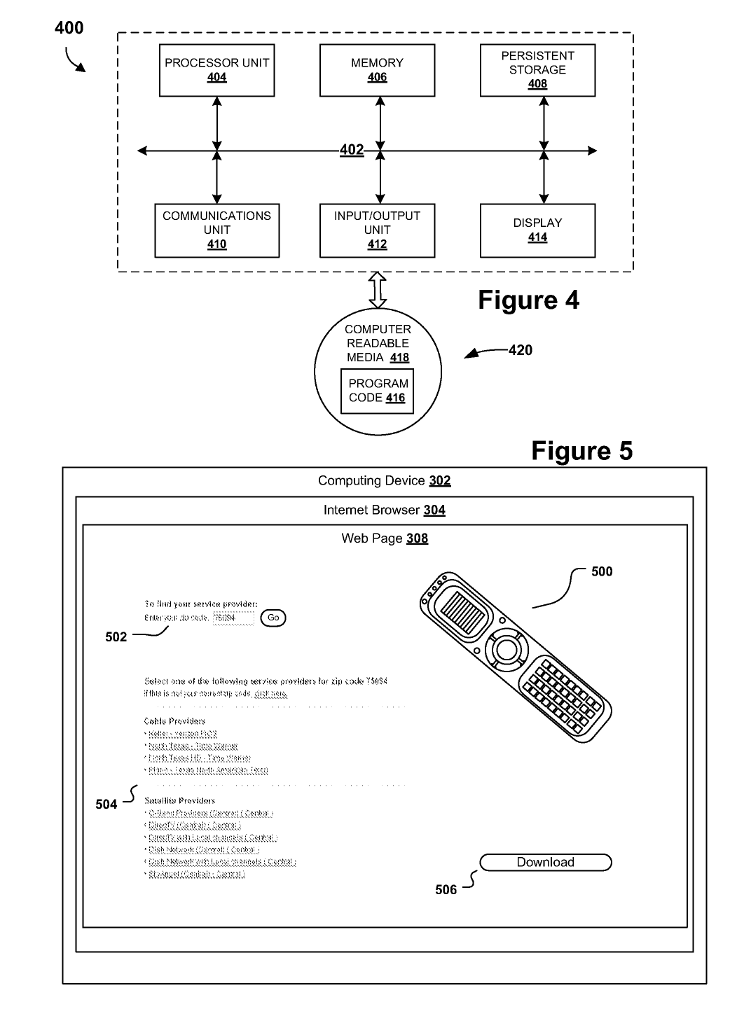

FIG. 4 is an embodiment of a data processing system in which illustrative embodiments may be implemented such as server 316 as depicted in FIG. 3. In this embodiment, data processing system 400 includes communications fabric 402, which provides communications between processor unit 404, memory 406, persistent storage 408, communications unit 410, input/output (I/O) unit 412, and display 414.

Processor unit 404 serves to execute instructions for software that may be loaded into memory 406. Processor unit 404 may be a set of one or more processors or may be a multi-processor core, depending on the particular implementation. Further, processor unit 404 may be implemented using one or more heterogeneous processor systems in which a main processor is present with secondary processors on a single chip. As another illustrative example, processor unit 404 may be a symmetric multi-processor system containing multiple processors of the same type.

In some embodiments, memory 406 may be a random access memory or any other suitable volatile or non-volatile storage device. Persistent storage 408 may take various forms depending on the particular implementation. For example, persistent storage 408 may contain one or more components or devices. Persistent storage 408 may be a hard drive, a flash memory, a rewritable optical disk, a rewritable magnetic tape, or some combination of the above. The media used by persistent storage 408 also may be removable such as, but not limited to, a removable hard drive.

Communications unit 410 provides for communications with other data processing systems or devices. In these examples, communications unit 410 is a network interface card. Modems, cable modem and Ethernet cards are just a few of the currently available types of network interface adapters. Communications unit 410 may provide communications through the use of either or both physical and wireless communications links.

Input/output unit 412 enables input and output of data with other devices that may be connected to data processing system 400. In some embodiments, input/output unit 412 may provide a connection for user input through a keyboard and mouse. Further, input/output unit 412 may send output to a printer. Display 414 provides a mechanism to display information to a user.

Instructions for the operating system and other applications or programs are located on persistent storage 408. These instructions may be loaded into memory 406 for execution by processor unit 404. The processes of the different embodiments may be performed by processor unit 404 using computer implemented instructions, which may be located in a memory, such as memory 406. These instructions are referred to as program code, computer usable program code, or computer readable program code that may be read and executed by a processor in processor unit 404. The program code in the different embodiments may be embodied on different physical or tangible computer readable media, such as memory 406 or persistent storage 408.

Program code 416 is located in a functional form on computer readable media 418 that is selectively removable and may be loaded onto or transferred to data processing system 400 for execution by processor unit 404. Program code 416 and computer readable media 418 form computer program product 420 in these examples. In one example, computer readable media 418 may be in a tangible form, such as, for example, an optical or magnetic disc that is inserted or placed into a drive or other device that is part of persistent storage 408 for transfer onto a storage device, such as a hard drive that is part of persistent storage 408. In a tangible form, computer readable media 418 also may take the form of a persistent storage, such as a hard drive, a thumb drive, or a flash memory that is connected to data processing system 400. The tangible form of computer readable media 418 is also referred to as computer recordable storage media. In some instances, computer readable media 418 may not be removable.

Alternatively, program code 416 may be transferred to data processing system 400 from computer readable media 418 through a communications link to communications unit 410 and/or through a connection to input/output unit 412. The communications link and/or the connection may be physical or wireless in the illustrative examples.

The different components illustrated for data processing system 400 are not meant to provide architectural limitations to the manner in which different embodiments may be implemented. The different illustrative embodiments may be implemented in a data processing system including components in addition to or in place of those illustrated for data processing system 400. Other components shown in FIG. 2 can be varied from the illustrative examples shown. For example, a storage device in data processing system 400 is any hardware apparatus that may store data. Memory 406, persistent storage 408, and computer readable media 418 are examples of storage devices in a tangible form.

FIG. 5 depicts an embodiment of a web page for, among other things, retrieving data that correlates channel names to channel numbers for at least one media provider. In some embodiments, web page 308 may require a user to sign in/register prior to enabling access. A user may view web page 308 using internet browser 304 executing on computing device 302. However, in some embodiments, web page 308 may be accessed directly from remote control device 100 in Hypertext Markup Language (HTML), WML, other mobile protocols, and/or text form without the use of computing device 302.

In some embodiments, web page 308 may be configured to enable a user to select the model or brand of remote control device 100. Web page 308 may display a picture 500 of the selected remote control device 100.

In addition, web page 308 may be configured to request location information 502 from a user to determine the media providers for a certain area. In some embodiments, location information 502 may be a postal zip code. However, in other embodiments, location information 502 may comprise other types of information such as, but not limited to, the city and state of a user. Further, in some embodiments, web page 308 may automatically determine the location information 502 by identifying the geographical location of an IP address or by other means such as, but not limited to, using the global positioning system (GPS). In some embodiments, remote control device 100 may transmit the location information to server 316. Moreover, in some embodiments, the list of media providers may be determined based upon some other criteria.

Once location information 502 is determined, web page 308 displays a list of available media providers 504 for the determined location. After web page 308 receives a user selection of a media provider from the list of available media providers 504, web page 308 may enable a download button 506 to enable a user to download the data that correlates channel names to channel numbers for the selected media provider.

However, in some embodiments, web page 308 may provide other functionalities not depicted in FIG. 5. For example, web page 308 may present several options for user such as, but not limited to, creating a favorites list, personalizing channel names, and/or retrieving data for operating remote control device 100 with a particular electronic device.

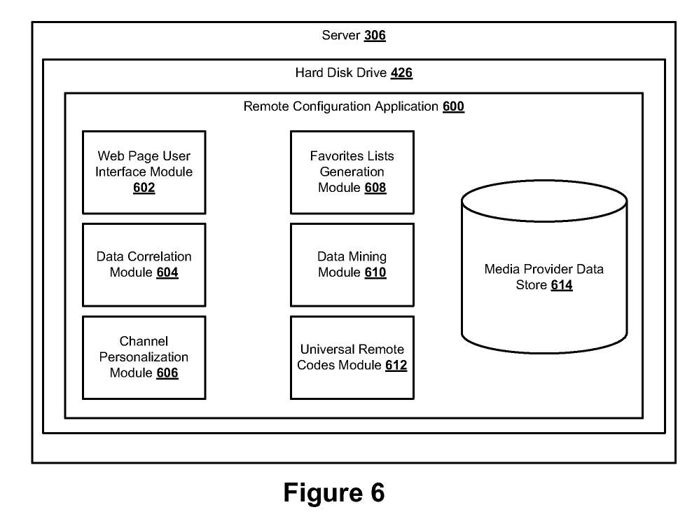

FIG. 6 depicts an embodiment of a remote configuration application for generating and performing the functions associated with web page 308. Remote configuration application 600 may be stored and executed by a data processing system such as, but not limited to, server 316. For example, remote configuration application 600 may be stored in storage devices, such as persistent storage 408, and may be loaded into memory 406 for execution by processing unit 404. In the depicted embodiment, remote configuration application 600 comprises of a web page user interface module 602, a data correlation module 604, a channel personalization module 606, a favorites lists generation module 608, a data mining module 610, a universal remote codes module 612, and media provider data store 614.

Web page user interface module 602 comprises, among other things, the instruction code written in a computer language such as, but not limited to, ASP.net or Java which generates the user interface of web page 308. In addition, web page user interface module 602 may comprise instruction code for either implementing or calling the functions associated with web page 308.

Data correlation module 604 comprises instruction code for retrieving the electronic programming guide for at least one specified media provider from media provider data store 614. In some embodiments, data correlation module 604 may retrieve the electronic programming guide and/or any other information from a remote source. In addition, in some embodiments, data correlation module 604 extracts from the retrieved electronic programming guide data that correlates channel names to channel numbers for the specified media provider. However, in some embodiments, data correlation module 604 may retrieve just the data that correlates channel names to channel numbers for the specified media provider.

Channel personalization module 606 comprises instruction code for enabling a user to associate a particular channel to a user specified name. For example, the Disney® Cartoon Channel is normally named TOONDIS. A user who may have difficulty in remembering this channel name. Therefore, the user may rename and associate the Disney® Cartoon Channel with another user specified name such as “kids.” In some embodiments, multiple personalized lists may be created. For example, a first user may correlate a channel with a personalized name and a second user may correlate the same channel with a different personalized name. In such embodiments, remote control device 100 may be configured to switch between different user profiles.

In addition, favorites list generation module 608 comprises instruction code for enabling a user to group together and name a list of channels. For example, a user may desire to group together all channels that broadcast home makeover shows such as, but not limited to, Home & Garden Television® (HGTV), The Learning Channel® (TLC), and the Do-It Yourself (DIY) channel®. In some embodiments, favorites list generation module 608 may enable the user to generate and download multiple lists. Remote control device 100 may be configured to switch between the multiple lists and cycle through the channels of the selected list. Alternatively, in some embodiments, remote control device 100 may generate and display the list in response to receiving the name of a desired list. A user may then select a desired channel from the displayed list. In some embodiments, multiple favorites lists may be created.

Data mining module 610 comprises instruction code for mining/searching through the data of one or more retrieved electronic programming guides for a specified media provider. For example, data mining module 610 may dynamically mine through a retrieved electronic programming guide to determine and group together all comedies. In some embodiments, data mining module 610 may dynamically determine and group together all shows containing a particular actor/actress. In some embodiments, remote control device 100 may be updated in real time with the mined data. Alternatively, in some embodiments, remote control device 100 is updated periodically to correspond to programming changes/updates. Further, in some embodiments, data mining module 610 may mine the data to enable a user to search through the downloaded electronic programming guides by keyword. For example, remote control device 100 may be configured to display a list of reality shows in response to a “reality” keyword search.

Furthermore, universal remote codes module 612 comprises instruction code for enabling a user to specify and download data for using remote control device 100 to control a specific electronic device. For example, a user may desire to control two different televisions and a DVD player with a single remote control device 100. Instead of having to manually lookup/enter possible codes and/or train remote control device 100 with another remote device to enable operation as currently taught by the prior art, universal remote codes module 612 retrieves the data for the specified device(s) and enables a user to download the data for enabling remote control device 100 to operate the specified device(s) in a user-friendly manner. Thus, a user is able to configure remote control device 100 to control multiple devices in a fraction of the time as compared to other known methods. Further, in some embodiments, remote control device 100 may be configured to group a set of devices together, switch between the set of devices, and/or switch on the devices within a set of devices in a predetermined order.

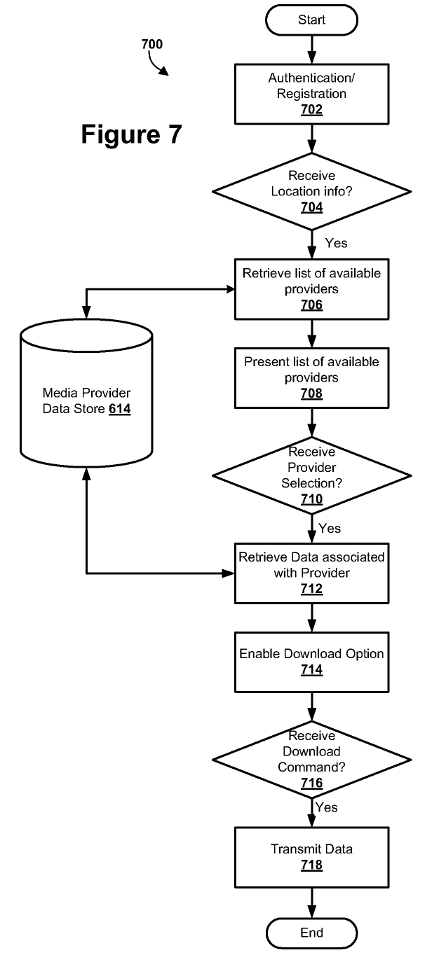

FIG. 7 is a flowchart for retrieving data that correlates channel names to channel numbers for at least one media provider in accordance with illustrative embodiments. The process of FIG. 7 may be performed by a data processing system such as server 400. Process 700 begins at block 702 by authenticating and/or registering a user by currently known methods. At block 704, the process determines if location information has been received. Once the location information is received, the process, at block 706, retrieves a list of available media providers for the given location information from either a local or remote media provider data store 614. The process presents the retrieved list of available media providers at block 708 and waits to receive a provider selection from the user at block 710. Responsive to receiving a provider selection, the process retrieves data correlating channel names to channel numbers for the selected media provider at block 712. The process then presents a download option to the user at block 714 and waits for a download command at block 716. Responsive to receiving the download command, the process transmits the data correlating channel names to channel numbers for the selected media provider at block 718, with the process terminating thereafter.

It should be understood by one of ordinary skill in the art that process 700 may be altered by adding, deleting, modifying, and/or combining the depicted blocks and that such modifications are within the scope of the disclosed embodiments. For example, in some embodiments, wherein the downloaded data is transferred from computing device 302 to remote control device 100, additional blocks may be added to process 700 for ensuring that remote control device 100 is properly connected to computing device 302 prior to transferring the data. Of course, additional error checking mechanisms may also be added to process 700. For example, an error may be presented if the location information is received in an improper format and/or is inconsistent with any known location. In addition, process 700 may present a successful completion message upon proper data transfer. In some embodiments, process 700 may be altered by including additional blocks to enable a user to create one or more favorites lists, personalize channel names, retrieve data for operating remote control device 100 with a particular electronic device and/or retrieve one or more electronic programming guides. Further, in some embodiments, configuration data may be downloaded in chunks, i.e., a portion at a time, to reduce bandwidth. Thus, if the transmission is disrupted, the transmission of the configuration data may resume near the disrupted point.

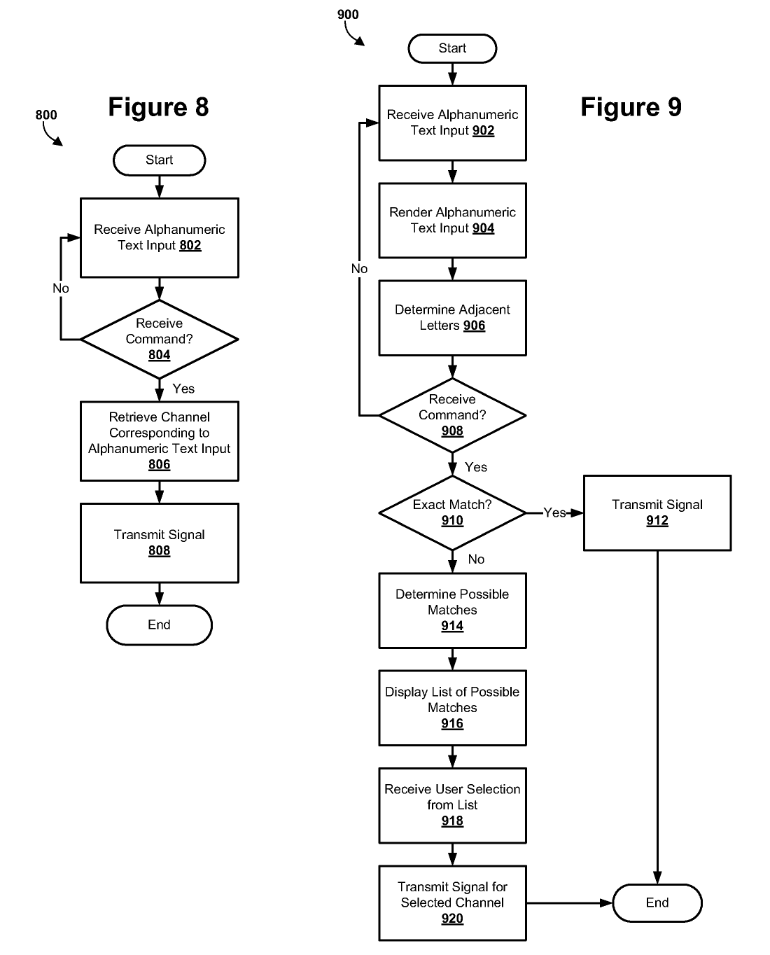

FIG. 8 is a flowchart for selecting a channel on an electronic device in accordance with an illustrative embodiment. Process 800 may be implemented by an embodiment of remote control device 100. Process 800 begins by receiving alphanumeric text input at block 802. The process waits, at block 804, for a command indicating that the user has finished entering in text, such as, but not limited to, an ENTER command. Responsive to receiving the command, the process retrieves the channel corresponding to entered text at block 806. At block 808, the process transmits a signal to change the channel on the electronic device to the channel corresponding to the entered text with the process terminating thereafter.

FIG. 9 is a flowchart for selecting a channel on an electronic device in accordance with another illustrative embodiment. Process 900 may be implemented by an embodiment of remote control device 100. Process 900 begins by receiving alphanumeric text input at block 902. At block 904, the process renders the alphanumeric text input on a display of remote control device 100 after each character is entered. The process also determines the adjacent letters associated with the entered character at block 906. The process determines at block 908 whether a command indicating that the user has finished entering in text is received such as, but not limited to, an ENTER command. If an ENTER command has not been received, the process returns to block 902 to receive additional alphanumeric text input. However, if an ENTER command is received at block 908, the process determines if the alphanumeric text input matches a stored channel name at block 910. If there is an exact match, the process, at block 912, transmits a signal to change the channel on the electronic device to the channel corresponding to the entered alphanumeric text, with the process terminating thereafter. However, if there is not an exact match, the process determines possible matches based on the entered text and the combination of adjacent characters at block 914. At block 916, the process displays a list of possible matching channel names. Responsive to receiving a user selection of a channel from the displayed list at block 918, the process transmits a signal to change the channel on the electronic device to the selected channel at block 920, with the process terminating thereafter.

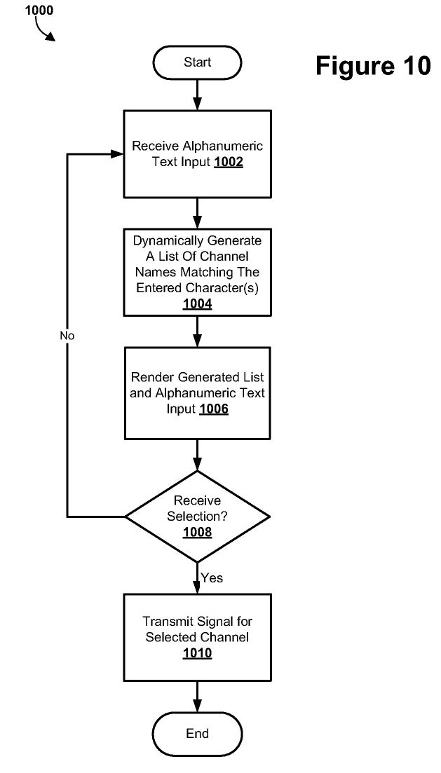

FIG. 10 is a flowchart for selecting a channel on an electronic device in accordance with another illustrative embodiment. Process 1000 may be implemented by an embodiment of remote control device 100. Process 1000 begins by receiving alphanumeric text input at block 1002. At block 1004, the process dynamically generates a list of channel names matching the entered character(s). Dynamically means the list of channel automatically updates after each entered character or after deletion of a character. The process renders the entered alphanumeric text input and the generated list of channel names on a display of remote control device 100 at block 1006. In some embodiments, if a unique match is found, the process transmits a signal to change the electronic device to the matching channel. The process waits for a user selection of a channel from the displayed list at block 1008. If no selection command is received, the process returns to block 1002. However, if a selection of a channel command is received, the process transmits a signal to change the channel on the electronic device to the selected channel at block 1010, with the process terminating thereafter.

FIGS. 7-10 are not intended to imply limitations on a specific type of implementation. It should be understood by one of ordinary skill in the art that numerous modifications can be made to the flowcharts depicted in FIGS. 7-10 and that such modifications are within the scope of the disclosed embodiments. For example, one of ordinary skill in the art may combine in whole or in part the processes depicted in FIGS. 7-10. Additional examples of modifications within the scope of the disclosed embodiments includes altering process 800 to provide some indication to the user that a non-matching channel name has been entered. In addition, process 900 may be altered to transmit a signal to change the channel on the electronic device to the most probable match based on past selections in the event that the entered alphanumeric text input does not exactly match a stored channel name. Process 1000 may be altered to display only the generated list of channels and/or may be altered to display a generated list of matching programs in addition to the matching channel names. In addition, process 1000 may be altered to include functionality for searching through stored electronic programming guides for programs matching a particular topic. For example, a user may simply enter in the term “golf” or some portion thereof and have remote control device 100 automatically switch to a channel broadcasting a golf tournament and/or present the user with a list of channels currently or in the near future will be broadcasting golf. Furthermore, although the disclosed embodiments refer to channels, it is within the scope of the disclosed embodiments, that remote control device 100 may be used to control other types of devices such as, but not limited to, radios/stereos. Thus, as referenced herein, the term “channel” also comprises radio station names or other types of station identifiers.

Accordingly, the disclosed embodiments overcome the disadvantages and limitations of the prior art by enabling a user to select a particular channel and/or program without having to know the specific channel number. Furthermore, the disclosed embodiments enable a user to configure a remote control device using a user friendly web interface. Moreover, the disclosed embodiments, enable a user to, among other things, create one or more favorites lists and personalize channel names.

1. A method for controlling an electronic device comprising:
configuring a remote control device to store data correlating channel names to channel numbers for at least one media provider;
configuring the remote control device to receive alphanumeric text input from a user;
configuring the remote control device to correlate the alphanumeric text input to a channel number using the data; and
configuring the remote control device to transmit a signal to the electronic device to switch the electronic device to the channel number in connection with receiving the alphanumeric text input.

2. The method of claim 1, further comprising configuring the remote control device to present the alphanumeric text input on a display.

3. The method of claim 1, further comprising:
configuring the remote control device to generate a dynamic list of channels matching the alphanumeric text input;
configuring the remote control device to present the dynamic list of channels on a display; and
configuring the remote control device to transmit a signal to the electronic device to switch the electronic device to a selected channel in response to receiving a selection command of the selected channel from the list of channels.

4. The method of claim 1, further comprising configuring the remote control device to dynamically correct user entry errors.

5. The method of claim 1, further comprising configuring the remote control device to associate a particular channel to a user-specified name.

6. The method of claim 1, further comprising configuring the remote control device to receive the data from a network.

7. The method of claim 1, further comprising configuring the remote control device to store usage data associated with selected channels.

8. The method of claim 1, further comprising configuring the remote control device to transmit usage data to a network.

9. The method of claim 1, configuring the remote control device to store data correlating channel names to channel numbers for a plurality of media providers.

10. The method of claim 1, further comprising configuring the remote control device to operate a particular electronic device using configuration data received over a network.

11. A remote control device comprising:
memory storing data correlating channel names to channel numbers;
a microcontroller for correlating alphanumeric text input to a channel number using the stored data; and
a transmitter for transmitting a signal to the electronic device to switch an electronic device to the channel number in connection with receiving the alphanumeric text input from a user.

12. The remote control device of claim 11, further comprising a display for displaying the alphanumeric text input.

13. The remote control device of claim 11, further comprising a network device for communicating over a network.

14. The remote control device of claim 11, further comprising a communication port for coupling the remote control device to a computing device.

15. An apparatus comprising:
a data bus system;
memory coupled to the data bus system, wherein the memory includes computer usable program code;
a processing unit coupled to the data bus system, wherein the processing unit executes the computer usable program code to produce data that correlates channel names to channel numbers for a specified media provider; and
a network communication device coupled to the data bus for transmitting the data.

16. The apparatus of claim 15, wherein the processing unit further executes the computer usable program code to produce configuration data to enable operation of a specified device and wherein the network communication device transmits the configuration data.

17. The apparatus of claim 15, wherein the processing unit further executes the computer usable program code to group together a plurality of selected channels.

18. The apparatus of claim 15, wherein the processing unit further executes the computer usable program code to analyze usage data associated with a remote control device.

19. The apparatus of claim 15, wherein the processing unit further executes the computer usable program code to associate a channel with a user specified name.

20. A method for controlling an electronic device comprising:
configuring a remote control device to store a list of favorite channels; and
configuring the remote control device to transmit a signal to the electronic device to switch the electronic device to a selected channel of the list of favorite channels.

21. The method of claim 20, wherein the list of favorite channels is received over a network.

22. The method of claim 21, wherein the list of favorite channels is personalized by a user at an internet website.

23. The method of claim 20, wherein the list of favorite channels is personalized using the remote control device.

24. The method of claim 20, further comprising configuring the remote control device to store a plurality of lists of favorite channels.

25. The method of claim 24, further comprising associating a personalized name with each list of favorite channels.

26. The method of claim 24, further comprising configuring the remote control device to switch between the plurality of lists of favorite channels.

27. The method of claim 26, further comprising configuring the remote control device to display the personalized name associated with each list of favorite channels.
